(19) United States
(12) Patent Application Publication
(10) Pub. No.: US 2017/0267700 A1
(43) Pub. Date: Sep. 21, 2017

(54) Precursors for Electron Beam-Induced Deposition of Gold and Silver

(71) Applicant: University of Florida Research Foundation, Inc., Gainesville, FL (US)

(72) Inventors: Lisa McElwee-White, Gainesville, FL (US); Jakub Pedziwiatr, Gainesville, FL (US); D. Howard Fairbrother, Baltimore, MD (US)

(21) Appl. No.: 15/505,359

(22) PCT Filed: Aug. 26, 2015
(86) PCT No.: PCT/US2015/046872

§ 371 Date: Feb. 21, 2017

Related U.S. Application Data
(60) Provisional application No. 62/042,530, filed on Aug. 27, 2014.

(51) Int. Cl. C07F 1/00; C23C 16/48

(52) U.S. Cl. CPC C07F 1/005; C23C 16/487

(57) ABSTRACT

Precursors are prepared and employed in electron beam induced decomposition (EBID). The EBID precursors are complexes of the formula: X-M-Y, where M is Au or Ag; X is F, Cl, Br, I, CN, OR¹, O₂CR², or R³; Y is P(OR)₃, NR₃, unsubstituted or substituted pyrrole, unsubstituted or substituted pyridine, unsubstituted or substituted pyrrolidine, or unsubstituted or substituted piperidine; and where R, R¹, R², R³, and substituents of the substituted pyrrole, pyridine, pyrrolidine, or piperidine are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl. The decomposition of the EBID precursor results in the formation of one or more gold, silver, or any combination thereof features on a substrate.

CROSS-REFERENCE TO A RELATED APPLICATION

This application claims the benefit of U.S. Provisional Application Ser. No. 62/042,530, filed Aug. 27, 2014, the disclosure of which is hereby incorporated by reference in its entirety, including all figures, tables and drawings.

### BACKGROUND OF INVENTION

The formation of thin films of metals using chemical vapor deposition (CVD) is of interest for applications in microelectronics, optical devices, wear protection, and catalysts. Very conductive and stable metal films are desirable. Gold films are particularly interesting because of their low resistivity (2.44 Ωcm) and high chemical corrosion resistance. Gold CVD has only limited gold precursor resources. Most known precursors are metallo-organic compounds containing C and/or O atoms and these elements from the precursor are incorporated into the thin films as impurities. Gold deposition by laser induced chemical vapor deposition (LCVD), electron-beam induced deposition (EBID) and local deposition in the tip-sample gap of a scanning tunneling microscope have been demonstrated. (Utke et al., J. Vac. Sci. Technol. B, 18, 3168 (2000)) Bimetallic deposition has been examined.

Electron beam induced deposition (EBID) is a direct write technique where precursor molecules adsorbed on a substrate are locally decomposed to a metallic film. The precursor molecules are delivered to the surface through a gas injection system (GIS), as a flow of vapor molecules from a condensed precursor contained in a reservoir. The decomposition is induced by the electron beam, producing non-volatile components that form a deposition on the surface and producing volatile components, which are pumped from the deposition surface using a vacuum system. Because of the small diameter of the electron beam and the excellent capability for patterning, the technique allows the direct creation of micro- and nano-scale three dimensional structures.

Most currently available precursors for EBID of gold result in deposits with extremely high levels of organic and inorganic contamination from electron stimulated ligand decomposition during the EBID process. Although ClAu(PF₃) (Fuss et al., Z Naturforsch. B, 47, 591 (1992) and ClAuCO Mulders et al., J. Phys. D: AppL Phys. 45 (2012) 475301) have both been used to deposit gold structures of fairly high purity, the sensitivity of these compounds towards temperature, air, moisture and light render both impractical for storage and scale-up to the quantities needed for practical applications. (Tran et al., J. Electrochem. Soc., 154 (10) D520-D525 (2007)) For silver, EBID processes in liquid phases have been reported, but there are currently no acceptable precursors for gas phase delivery, which is the method used in commercial EBID tools.

There remains a need for superior precursors for EBID preparation of metal-containing deposits for repair of lithographic masks and for deposition of metals for circuit edit and other repair in the semiconductor industry. Additionally, these depositions of size and shape controlled features have potential for applications in catalysis and plasmonics.

### BRIEF SUMMARY

Embodiments of the invention are directed to electron beam induced deposition (EBID) precursors that are gold and silver phosphite or amine complexes of the formula: X-M-Y, where M is Au or Ag; X is F, Cl, Br, I, CN, OR¹, O₂CR², or R³; Y is P(OR)₃, NR₃, unsubstituted or substituted pyrrole, unsubstituted or substituted pyridine, unsubstituted or substituted pyrrolidine, or unsubstituted or substituted piperidine; where R, R¹, R², R³, and substituents on the substituted pyrrole, pyridine, pyrrolidine, or piperidine are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl.

Other embodiments of the invention are directed to a method for the preparation of deposited features of gold, silver, or any combination thereof by EBID, ion beam, or chemical vapor deposition techniques from the EBID precursor complexes of the formula X-M-Y.

### DETAILED DISCLOSURE

Embodiments of the invention are directed to EBID precursors that are gold and silver phosphite or amine complexes of the formula:

X-M-Y,

where M is Au or Ag; X is F, Cl, Br, I, CN, OR¹, O₂CR², or R³; Y is P(OR)₃, NR₃, unsubstituted or substituted pyrrole, unsubstituted or substituted pyridine, unsubstituted or substituted pyrrolidine, or unsubstituted or substituted piperidine; and where R, R¹, R², R³, and substituents of the substituted pyrrole, pyridine, pyrrolidine, or piperidine are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl.

The gold and silver complexes display a low coordination number where the electronic properties of the ligands render the complexes suitable for deposition of metal-containing structures. The nature of the ligands should result in very low levels of contaminants relative to those from current commercially available precursors. The alkoxide, amine, carboxylate, and phosphite ligands of these complexes are unknown as Au(I) or Ag(I) EBID precursors.

In an embodiment of the invention, the complex is a gold or silver phosphite complex of the formula:

X-M-P(OR)₃

where M=Au or Ag; X=F, Cl, Br, I or CN; R is independently H, C₁-C₈ alkyl, aryl, C₁-C₈ perfluoroalkyl, C₁-C₈ partially fluorinated alkyl, and silicon-containing groups of the type SiR⁵R⁶R⁷.

In another embodiment of the invention the complex is a gold or silver phosphite complex of the formula:

R¹O-M-P(OR)₃

where M=Au or Ag; R and R₁ are independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

In another embodiment of the invention the complex is a gold or silver phosphite complex of the formula:

R²CO₂-M-P(OR)₃

where M=Au or Ag; R and R² are independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

In another embodiment of the invention the complex is a gold or silver phosphite complex of the formula:

R³-M-P(OR)₃

where M=Au or Ag; R and R³ are independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

In another embodiment of the invention the complex is a gold or silver amine complex of the formula:

X-M-NR⁴₃

where M=Au or Ag; X=F, Cl, Br, I or CN; R⁴ is independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

In another embodiment of the invention the complex is a gold or silver amine complex of the formula:

R¹O-M-NR⁴₃

where M=Au or Ag; R¹ and R⁴ are independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

In another embodiment of the invention the complex is a gold or silver amine complex of the formula:

R²CO₂-M-NR⁴₃

where M=Au or Ag; R² and R⁴ are independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

In another embodiment of the invention the complex is a gold or silver amine complex of the formula:

R³-M-NR⁴₃

where M=Au or Ag; R³ and R⁴ are selected from the group consisting of H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

In another embodiment of the invention the complex is a gold or silver pyrrole complex of the formula:

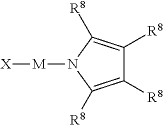

where M is Au or Ag; X is F, Cl, Br, I, CN, OR¹, O₂CR², or R³; and where R¹, R², R³, and R⁸ are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl.

In another embodiment of the invention the complex is a gold or silver pyridine complex of the formula:

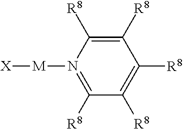

where M is Au or Ag; X is F, Cl, Br, I, CN, OR¹, O₂CR², or R³; and where R¹, R², R³, and R⁸ are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl.

In another embodiment of the invention the complex is a gold or silver pyrrolidine complex of the formula:

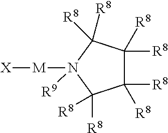

where M is Au or Ag; X is F, Cl, Br, I, CN, OR¹, O₂CR², or R³; and where R¹, R², R³, R⁸, and R⁹ are independently H, C₁-C₈ alkyl, C₆-C₁₀aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl.

In another embodiment of the invention the complex is a gold or silver piperidine complex of the formula:

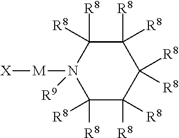

where M is Au or Ag; X is F, Cl, Br, I, CN, OR¹, O₂CR², or R³; and where R¹, R², R³, R⁸, and R⁹ are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁₀-C₈ alkyl, or C₁-C₈ fluorinated alkyl.

In another embodiment of the invention, one or more of the gold and/or silver phosphite or amine complexes are introduced as a metal deposition precursor into an EBID in a gaseous state to deposit gold and/or silver metal with a desired shape and size. The electron beam induced deposition (EBID) provides a metal feature on a substrate where at least one dimension of the metal feature is 0.2 to 1,000 nanometers or more. The substrate can be any substrate that is not adversely affected by the electron beam, including semiconductors, conductors, or insulators, for example, Si or SiO₂. For example the deposition can be a circuit element that has a width of 1 to 5 nm, 1 to 10 nm, 1 to 15 nm, 1 to 20 nm, 1 to 30 nm, 1 to 40 nm, 1 to 50 nm, 1 to 100 nm, 1 to 100 nm. Focused EBID (FEBID) units provide the finer features with very thin features. By applying a raster scan during deposition of the metal, larger surfaces can be covered with surface areas exceeding one square micron. The metal EBID precursors can be used alone or in combination of metal EBID precursors. In an embodiment of the invention, the gold and/or silver phosphite or amine complexes can be combined with one or more co-precursors selected from H₂, O₂, O₃, N₂O, NO, CO or X₂ where X=F, Cl, Br or I.

The EBID and FEBID equipment and processes are well documented. The method can be carried out with the equipment and in the manner described in: Mulders et al., J Phys. D: Appl. Phys. 45 (2012) 475301; Utke et al., J. Vac. Sci. Technol. B 26 (4) (2008) 1197-272; Brintlinger et al., J. Vac. Sci. Technol. B 23 (6) (2005); Bresin et al., Angew. Chem. Int. Ed. 2013, 52, 8004-7; and Spencer et al., Appl. Phys. A (2014) DOI 10.1007/s00339-014-8570-5.

All publications referred to or cited herein are incorporated by reference in their entirety, including all figures and tables, to the extent they are not inconsistent with the explicit teachings of this specification.

It should be understood that the embodiments described herein are for illustrative purposes only and that various modifications or changes in light thereof will be suggested to persons skilled in the art and are to be included within the spirit and purview of this application.

I claim:

1. An electron beam induced deposition EBID precursor, comprising a complex of the formula:
X-M-Y,
where M is Au or Ag; X is F, Cl, Br, I, CN, OR¹, O₂CR², or R³; Y is P(OR)₃, NR₃, unsubstituted or substituted pyrrole, unsubstituted or substituted pyridine, unsubstituted or substituted pyrrolidine, or unsubstituted or substituted piperidine; and where R, R¹, R², R³, and substituents of the substituted pyrrole, pyridine, pyrrolidine, or piperidine are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl.

2. The EBID precursor according to claim 1, wherein the complex has the formula:
X-M-P(OR)₃,
where M=Au or Ag; X=F, Cl, Br, I or CN; R is independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

3. The EBID precursor according to claim 1, wherein the complex has the formula:
R¹-M-P(OR)₃,
where M=Au or Ag; R and R¹ are independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

4. The EBID precursor according to claim 1, wherein the complex has the formula:
R²CO₂-M-P(OR)₃,
where M=Au or Ag; R and R² are independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

5. The EBID precursor according to claim 1, wherein the complex has the formula:
R³-M-P(OR)₃,
where M=Au or Ag; R and R³ are independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

6. The EBID precursor according to claim 1, wherein the complex has the formula:
X-M-NR⁴₃,
where M=Au or Ag; X=F, Cl, Br, I or CN; R⁴ is independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

7. The EBID precursor according to claim 1, wherein the complex has the formula:
R¹O-M-NR⁴₃,
where M=Au or Ag; R¹ and R⁴ are independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

8. The EBID precursor according to claim 1, wherein the complex has the formula:
R²CO₂-M-NR⁴₃,
where M=Au or Ag; R² and R⁴ are independently H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

9. The EBID precursor according to claim 1, wherein the complex has the formula:
R³-M-NR⁴₃,
where M=Au or Ag; R³ and R⁴ are selected from the group consisting of H, C₁-C₈ alkyl, aryl, C₁-C₈ perfluoroalkyl, C₁-C₈ partially fluorinated alkyl, and silicon-containing groups of the type SiR⁵R⁶R⁷ where R⁵, R⁶, and R⁷ are independently H, C₁-C₈ alkyl, or C₁-C₈ fluorinated alkyl.

10. The EBID precursor according to claim 1, wherein the complex has the formula: 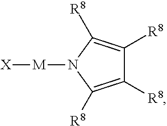
where M is Au or Ag; X is F, Cl, Br, I, CN, OR¹, O₂CR², or R³; and where R¹, R², R³, and R⁸ are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl.

11. The EBID precursor according to claim 1, wherein the complex has the formula: 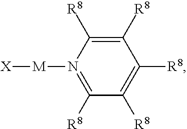
where M is Au or Ag; X is F, Cl, Br, I, CN, OR¹, O₂CR², or R³; and where R¹, R², R³, and R⁸ are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl.

12. The EBID precursor according to claim 1, wherein the complex has the formula: 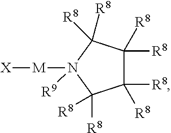
where M is Au or Ag; X is F, Cl, Br, I, CN, OR¹, O₂CR², or R³; and where R¹, R², R³, R⁸, and R⁹ are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl.

13. The EBID precursor according to claim 1, wherein the complex has the formula: 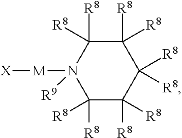
where M is Au or Ag; X is F, Cl, Br, I, CN, OR¹, O₂CR², or R³; and where R¹, R², R³, R⁸, and R⁹ are independently H, C₁-C₈ alkyl, C₆-C₁₀ aryl, C₁-C₈ perfluoroalkyl, C₁-C₈ partially fluorinated alkyl, and SiR⁵R⁶R⁷ where R⁵, R⁶, and R⁷ are independently H, C₁-C₈ alkyl, or C₁-C₈ fluorinated alkyl.

14. A method of depositing a metal feature, comprising:
providing a substrate;
providing a focused electron beam on a portion of the surface of the substrate;
introducing at least one EBID precursor according to claim 1 into a EBID device over the surface of the substrate;
decomposing the EBID precursor into a metal feature at the portion of the surface of the substrate having the focused electron beam.

15. The method of claim 14, further comprising introducing with the EBID precursor one or more co-precursors selected from H₂, O₂, O₃, N₂O, NO, CO and X₂ where X=F, Cl, Br or I.
